(19) United States
(12) Patent Application Publication
(10) Pub. No.: US 2026/0189212 A1
(43) Pub. Date: Jul. 2, 2026

(54) SURFACE ACOUSTIC WAVE DEVICE WITH INTERDIGITAL TRANSDUCER ELECTRODE HAVING DIFFERENT MASSES ON DIFFERENT HALF SIDES

(71) Applicant: Skyworks Solutions, Inc., Irvine, CA (US)

(72) Inventors: Satoru Ikeuchi, Ashiya-Shi (JP); Hisanori Aizawa, Osaka-Shi (JP); Rei Goto, Osaka-Shi (JP)

(21) Appl. No.: 19/413,310

(22) Filed: Dec. 9, 2025

Related U.S. Application Data
(60) Provisional application No. 63/738,934, filed on Dec. 26, 2024.
(60) Provisional application No. 63/738,942, filed on Dec. 26, 2024.
(60) Provisional application No. 63/738,935, filed on Dec. 26, 2024.

(51) Int. Cl. H03H 9/02; H03H 9/145; H03H 9/64

(52) U.S. Cl. CPC H03H 9/02992; H03H 9/145; H03H 9/64

(57) ABSTRACT

A surface acoustic wave device is disclosed. The surface acoustic wave device can include a piezoelectric layer. An interdigital transducer electrode can be in electrical communication with the piezoelectric layer. The interdigital transducer electrode can include a first bus bar. First fingers can extend from the first bus bar. The interdigital transducer electrode can include a second bus bar. Second fingers can extend from the second bus bar. The interdigital transducer electrode can have a first side and a second side separated by a centerline between the first bus bar and the second bus bar. A first mass of the first side of the interdigital transducer electrode can be different from a second mass of the second side of the interdigital transducer electrode. The first fingers can be asymmetric about the centerline in an active region of the surface acoustic wave device. A piston-mode structure can be asymmetric about the centerline between the first bus bar and the second bus bar.

### INCORPORATION BY REFERENCE TO ANY PRIORITY APPLICATIONS

Any and all applications for which a foreign or domestic priority claim is identified in the Application Data Sheet as filed with the present application, including U.S. Provisional Ser. No. 63/738,934 , filed on Dec. 26, 2024, titled “SURFACE ACOUSTIC WAVE DEVICE WITH INTERDIGITAL TRANSDUCER ELECTRODE HAVING DIFFERENT MASSES ON DIFFERENT HALF SIDES,” U.S. Provisional Ser. No. 63/738,942 , filed on Dec. 26, 2024, titled “SURFACE ACOUSTIC WAVE DEVICE WITH ASYMMETRIC INTERDIGITAL TRANSDUCER ELECTRODE FINGERS IN ACTIVE REGION,” and U.S. Provisional Ser. No. 63/738,935 , filed on Dec. 26, 2024, titled “SURFACE ACOUSTIC WAVE DEVICE WITH ASYMMETRIC PISTON-MODE STRUCTURE” are hereby incorporated by reference under 37 CFR 1.57 in their entirety herein.

### BACKGROUND

### Field

Embodiments of this disclosure relate to surface acoustic wave devices and, more specifically, to surface acoustic wave devices with an asymmetric interdigital transducer electrode.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transducer electrode on a piezoelectric substrate. The surface acoustic wave resonator can generate a surface acoustic wave on a surface of the piezoelectric layer on which the interdigital transducer electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, a surface acoustic wave device may comprise a piezoelectric layer. The surface acoustic wave device may comprise an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may have a first side and a second side separated by a centerline between the first bus bar and the second bus bar. A first mass of the first side of the interdigital transducer electrode may be different from a second mass of the second side of the interdigital transducer electrode.

In some embodiments, a difference between the first mass and the second mass may be in a range between 0.5% and 4% of the first mass.

In some embodiments, a difference between the first mass and the second mass may be in a range between 18% and 22% of the first mass.

In some embodiments, a size of the first bus bar and a size of the second bus bar may be different.

In some embodiments, a length of the first fingers and a length of the second fingers may be different.

In some embodiments, a gap between the first fingers and the second bus bar and a gap between the second fingers and the first bus bar may be different.

In some embodiments, the surface acoustic wave device may have an active region including a first border region, a second border region, and a center region between the first and second border regions. The first fingers may have a greater mass in the second border region than in the first border region.

In some embodiments, the first fingers in the first border region may be made with a first material. The second fingers in the second border region may be made with a second material different from the first material.

In some embodiments, the first fingers in the first border region may have a first width. The second fingers in the second border region may have a second width different from the first width.

In some embodiments, the first fingers in the first border region may have a first thickness. The second fingers in the second border region may have a second thickness different from the first thickness.

In some embodiments, the interdigital transducer electrode may further include a first mini-bus bar between the first bus bar and the second fingers.

In some embodiments, the interdigital transducer electrode may further include a second mini-bus bar between the second bus bar and the first fingers. The first mini-bus bar may have a greater width than the second mini-bus bar.

In some embodiments, the interdigital transducer electrode may further include first dummy fingers between the first bus bar and the second fingers.

In some embodiments, the interdigital transducer electrode may further include second dummy fingers between the second bus bar and the first fingers.

In some embodiments, the first dummy fingers may have a length that may be greater than a length of the second dummy fingers.

In some embodiments, the piezoelectric layer may have a trench.

In some embodiments, the surface acoustic wave device may further comprise a support substrate and an intermediate layer between the support substrate and the piezoelectric layer.

In some aspects, a surface acoustic wave device may comprise a piezoelectric layer. The surface acoustic wave device may comprise an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may be mass-asymmetric about a centerline between the first bus bar and the second bus bar.

In some embodiments, the interdigital transducer electrode may have a first side and a second side separated by the centerline between the first bus bar and the second bus bar. A first mass of the first side of the interdigital transducer electrode may be greater than a second mass of the second side of the interdigital transducer electrode.

In some embodiments, the surface acoustic wave device may have an active region including a first border region, a second border region, and a center region between the first and second border regions. The center region may be symmetric about the centerline.

In some aspects, an acoustic wave filter may comprise a surface acoustic wave device including a piezoelectric layer and an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may have a first side and a second side separated by a centerline between the first bus bar and the second bus bar. A first mass of the first side of the interdigital transducer electrode may be different from a second mass of the second side of the interdigital transducer electrode. The acoustic wave filter may comprise one or more other acoustic wave devices coupled to the surface acoustic wave device.

In some aspects, a surface acoustic wave device may comprise a piezoelectric layer. The surface acoustic wave device may comprise an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may have a first side and a second side separated by a centerline between the first bus bar and the second bus bar. The first fingers may be asymmetric about the centerline in an active region of the surface acoustic wave device.

In some embodiments, the first fingers in the active region may have a first length in the first side and a second length different from the first length in the second side.

In some embodiments, the active region may include a first border region, a second border region, and a center region between the first and second border regions. The first fingers may have a first mass in the first border region and a second mass in the second border region.

In some embodiments, a difference between the first mass and the second mass may be in a range between 0.5% and 4% of the first mass.

In some embodiments, a difference between the first mass and the second mass may be in a range between 18% and 22% of the first mass.

In some embodiments, the first fingers may have a first material in the first border region and a second material different from the first material in the second border region.

In some embodiments, the first fingers may have a first width in the first border region and a second width different from the first width in the second border region.

In some embodiments, the first fingers may have a first thickness in the first border region and a second thickness different from the first thickness in the second border region.

In some embodiments, the interdigital transducer electrode may further include a first mini-bus bar between the first bus bar and the second fingers.

In some embodiments, the interdigital transducer electrode may further include a second mini-bus bar between the second bus bar and the first fingers. The first mini-bus bar may have a greater width than the second mini-bus bar.

In some embodiments, the interdigital transducer electrode may further include first dummy fingers between the first bus bar and the second fingers.

In some embodiments, the interdigital transducer electrode may further include second dummy fingers between the second bus bar and the first fingers.

In some embodiments, the first dummy fingers may have a length that may be greater than a length of the second dummy fingers.

In some embodiments, the piezoelectric layer may have a trench.

In some embodiments, the surface acoustic wave device may further comprise a support substrate and an intermediate layer between the support substrate and the piezoelectric layer.

In some aspects, a surface acoustic wave device may comprise a piezoelectric layer. The surface acoustic wave device may comprise an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may have a first side and a second side separated by a centerline between the first bus bar and the second bus bar. The first fingers in an active region of the surface acoustic wave device may have a first length in the first side and a second length different from the first length in the second side.

In some embodiments, a first gap between the first fingers and the second bus bar may be greater than a second gap between the second fingers and the first bus bar.

In some aspects, an acoustic wave filter may comprise a surface acoustic wave device including a piezoelectric layer and an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may have a first side and a second side separated by a centerline between the first bus bar and the second bus bar. The first fingers may be asymmetric about the centerline in an active region of the surface acoustic wave device.

In some embodiments, a size of the first bus bar and a size of the second bus bar may be different.

In some embodiments, the first fingers in the active region may have a first length in the first side and a second length different from the first length in the second side.

In some aspects, a surface acoustic wave device may comprise a piezoelectric layer. The surface acoustic wave device may comprise an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The surface acoustic wave device may comprise a piston-mode structure asymmetric about a centerline between the first bus bar and the second bus bar.

In some embodiments, the surface acoustic wave device may include an active region having a first border region, a second border region, and a center region between the first and second border regions. The piston-mode structure may include a first hammer head structure in the first border region.

In some embodiments, the piston-mode structure may further include a second hammer head structure in the second border region.

In some embodiments, the first hammer head structure may have a first length. The second hammer head structure may have a second length different from the first length.

In some embodiments, the first hammer head structure may have a first width. The second hammer head structure may have a second width different from the first width.

In some embodiments, the first hammer head structure may have a first thickness. The second hammer head structure may have a second thickness different from the first thickness.

In some embodiments, the piston-mode structure may include a first mini-bus bar between the first bus bar and the second fingers.

In some embodiments, the piston-mode structure may further include a second mini-bus bar between the second bus bar and the first fingers. The first mini-bus bar may have a greater width than the second mini-bus bar.

In some embodiments, the piston-mode structure may include first dummy fingers between the first bus bar and the second fingers.

In some embodiments, the piston-mode structure may further include second dummy fingers between the second bus bar and the first fingers.

In some embodiments, the first dummy fingers may have a length that may be greater than a length of the second dummy fingers.

In some embodiments, the piezoelectric layer may have a trench.

In some embodiments, the surface acoustic wave device may further comprise a support substrate and an intermediate layer between the support substrate and the piezoelectric layer.

In some aspects, a surface acoustic wave device may include an active region having a first border region, a second border region, and a center region between the first and second border regions. The surface acoustic wave device may comprise a piezoelectric layer. The surface acoustic wave device may comprise an interdigital transducer electrode in electrical communication with the piezoelectric layer. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The interdigital transducer electrode may include a first hammer head structure in the first border region. The interdigital transducer electrode may include a second hammer head structure in the second border region. The first hammer head structure may have a first mass. The second hammer head structure may have a second mass different from the first mass.

In some embodiments, a difference between the first mass and the second mass may be in a range between 0.5% and 4% of the first mass.

In some embodiments, a difference between the first mass and the second mass may be in a range between 18% and 22% of the first mass.

In some embodiments, the first hammer head structure may have a first length. The second hammer head structure may have a second length different from the first length.

In some embodiments, the first hammer head structure may have a first width. The second hammer head structure may have a second width different from the first width.

In some embodiments, the first hammer head structure may have a first thickness. The second hammer head structure may have a second thickness different from the first thickness.

In some aspects, an acoustic wave filter may comprise a surface acoustic wave device including a piezoelectric layer, an interdigital transducer electrode in electrical communication with the piezoelectric layer, and a piston-mode structure. The interdigital transducer electrode may include a first bus bar. The interdigital transducer electrode may include first fingers extending from the first bus bar. The interdigital transducer electrode may include a second bus bar. The interdigital transducer electrode may include second fingers extending from the second bus bar. The piston-mode structure may be asymmetric about a centerline between the first and second bus bars.

In some embodiments, the piston-mode structure may include a hammer head structure, a mini-bus bar, or a dummy finger.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device according to an embodiment.

FIG. 1B is a schematic top plan view of the SAW device.

FIG. 2 is a graph showing a simulated wave displacement of the SAW device shown in FIGS. 1A and 1B.

FIG. 3A is a schematic cross-sectional side view of a surface acoustic wave (SAW) device according to an embodiment.

FIG. 3B is a schematic top plan view of the SAW device.

FIGS. 4A and 4C are graphs showing simulated wave displacements of the SAW device shown in FIGS. 3A and 3B.

FIGS. 4B and 4D are graphs showing simulated wave displacements of symmetric SAW devices.

FIG. 5A is a schematic top plan view of a symmetric SAW device.

FIGS. 5B to 5H are schematic top plan views of SAW devices that include piston mode structures according to various embodiments.

FIG. 6A is a schematic top plan view of a symmetric SAW device that includes piezoelectric layer trenches.

FIGS. 6B to 6E are schematic cross-sectional side views of the symmetric SAW device of FIG. 6A.

FIGS. 7A and 7B are schematic top plan views of SAW devices according to various embodiments.

FIG. 8A is a schematic diagram of a transmit filter that includes a surface acoustic wave resonator according to an embodiment.

FIG. 8B is a schematic diagram of a receive filter that includes a surface acoustic wave resonator according to an embodiment.

FIG. 9 is a schematic diagram of a radio frequency module that includes a surface acoustic wave resonator according to an embodiment.

FIG. 10 is a schematic diagram of a radio frequency module that includes filters with surface acoustic wave resonators according to an embodiment.

FIG. 11 is a schematic block diagram of a module that includes an antenna switch and duplexers that include a surface acoustic wave resonator according to an embodiment.

FIG. 12A is a schematic block diagram of a module that includes a power amplifier, a radio frequency switch, and duplexers that include a surface acoustic wave resonator according to an embodiment.

FIG. 12B is a schematic block diagram of a module that includes filters, a radio frequency switch, and a low noise amplifier according to an embodiment.

FIG. 13A is a schematic block diagram of a wireless communication device that includes a filter with a surface acoustic wave resonator in accordance with one or more embodiments.

FIG. 13B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate surface acoustic wave (MPS-SAW) device and a temperature compensated surface acoustic wave (TC-SAW) device.

Precise and efficient wave dynamics can be important for surface acoustic wave (SAW) devices, including SAW resonators, to achieve their desired performance. Key factors such as resonator efficiency, harmonic distortion, energy leakage, frequency stability, coupling uniformity, and non-linearity are critical to their operation. Non-linearity (e.g., the deviation of its response from a linear relationship between the input signal and the output signal) in SAW devices affects signal fidelity and limits the dynamic range.

Asymmetric displacement in SAW resonators can impact these performance factors. For example, asymmetric displacement can disrupt energy distribution, reducing resonator efficiency by scattering energy away from the intended acoustic path. It can introduce harmonic distortion and mode conversion, creating spurious signals that degrade signal fidelity and may interfere with nearby systems. Also, asymmetric displacement can introduce uneven stress and strain, exacerbating non-linearities and generating harmonic distortions. Such degradations can impair the resonator's functionality and limit its application. Providing symmetric displacement can mitigate these issues by providing even energy distribution and uniform coupling.

A SAW device can include an interdigital transducer (IDT) electrode having a first bus bar, first fingers that extend from the first bus bar, a second bus bar, and second fingers that extend from the second bus bar. The SAW device is substantially symmetric about a centerline between the first and second bus bars. A substantially symmetric SAW device has a mass difference between a first side and a second side about the centerline less than about 0.1%. However, despite such symmetry, the wave displacement in the SAW device can be asymmetric, in some applications. Therefore, achieving symmetric wave displacement in SAW devices can be challenging.

Embodiments disclosed herein relate to SAW devices that generate a substantially or effectively symmetric wave displacement. A SAW device according to some embodiments can include a piezoelectric layer and an interdigital transducer (IDT) electrode in electrical communication with the piezoelectric layer. The IDT electrode can include a first bus bar, first fingers that extend from the first bus bar, a second bus bar, and second fingers that extend from the second bus bar. The IDT electrode has a first side and a second side separated by a centerline between the first and second bus bars. The SAW device is asymmetric about the centerline between the first and second bus bars. In some embodiments, the IDT electrode is asymmetric (e.g., mass-asymmetric or structural-asymmetric) about the centerline between the first and second bus bars. In some embodiments, the first and second fingers are asymmetric about the centerline in an active region of the SAW device. The IDT includes a first electrode structure having the first bus bar and the first fingers, and a second electrode structure having the second bus bar and the second fingers. In some embodiments, a profile of the first electrode structure is different from a profile of the second electrode structure. In some embodiments, a piston-mode structure that is asymmetric about a centerline between the first bus bar and the second bus bar can also be included in the SAW device.

The extent of asymmetry of the SAW device can depend at least in part on a crystal orientation or a cut angle of the piezoelectric layer. The extent of asymmetry can mean a magnitude, an amount, or a degree of asymmetry or how much the asymmetric structure deviates from a symmetric structure. When the IDT electrode is asymmetric (e.g., mass-asymmetric or structural-asymmetric) about the centerline between the first and second bus bars, the extent of asymmetry can mean a magnitude, an amount, or a degree of different between a first side and a second side opposite the first side about the centerline. For example, when the first side and the second side of the IDT electrode have a magnitude of asymmetric deviation, it can mean that the first side is different in terms of mass, dimension, shape, and/or structure from the second side by the magnitude. In some embodiments, the magnitude can relate to how much the cut angle of the piezoelectric layer deviates from a reference angle (e.g., 0 or 90 degrees). Various embodiments of asymmetric SAW devices disclosed herein can provide improved resonator efficiency, harmonic distortion, energy leakage, frequency stability, coupling uniformity, and/or non-linearity.

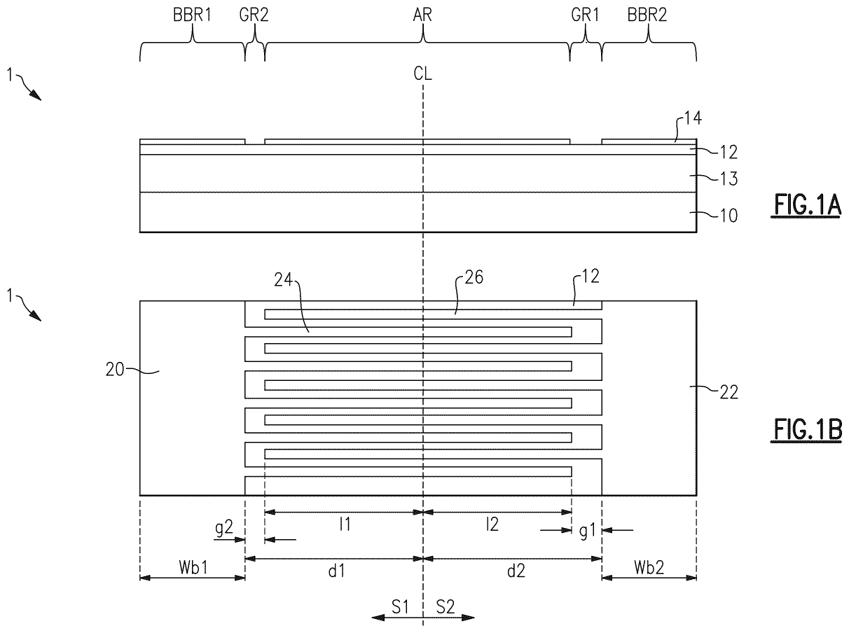

FIG. 1A is a schematic cross-sectional side view of a surface acoustic wave (SAW) device 1 according to an embodiment. FIG. 1B is a schematic top plan view of the SAW device 1. The surface acoustic wave device 1 is an example of a multilayer piezoelectric substrate surface acoustic wave (MPS-SAW) device. The principles and advantages disclosed herein may be implemented in any SAW device, such as, a temperature compensated surface acoustic wave (TC-SAW) device.

The SAW device 1 is an example of an asymmetric SAW device. The SAW device 1 can include a support substrate 10, a piezoelectric layer 12, an intermediate layer 13 between the support substrate 10 and the piezoelectric layer 12, and an interdigital transducer (IDT) electrode 14 in electrical communication with the piezoelectric layer 12. In the SAW device 1, the IDT electrode 14 can have asymmetric bus bar widths and/or asymmetric finger lengths that makes the SAW device an asymmetric SAW device.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high acoustic impedance. An acoustic impedance of the support substrate 10 can be higher than an acoustic impedance of the piezoelectric layer 12. For instance, the support substrate 10 can have a higher acoustic impedance than an acoustic impedance of lithium niobate and a higher acoustic impedance than lithium tantalate. The acoustic impedance of the support substrate 10 can be higher than an acoustic impedance of silicon dioxide (SiO₂). The SAW resonator 1 including the piezoelectric layer 12 on a support substrate 10 with relatively high thermal conductivity, such as silicon substrate, can achieve better thermal dissipation compared to a similar SAW resonator without the high impedance support substrate 10.

The piezoelectric layer 12 can include any suitable piezoelectric layer, such as a lithium based piezoelectric layer. In some embodiments, the piezoelectric layer 12 can be a lithium tantalate (LT) layer. For example, the piezoelectric layer 12 can be an LT layer having a cut angle of 20° (20 ° Y-cut X-propagation LT) or a cut angle of 60°(60 ° Y-cut X-propagation LT). For example, the piezoelectric layer 12 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 12. For example, the piezoelectric layer 12 can be an LN layer having a cut angle of about 118° (118 ° Y-cut X-propagation LN) or more or a cut angle of about 132° (132 Y-cut X-propagation LN) or less. For example, the piezoelectric layer 12 can be 125±20° Y-cut LN, 125±15° Y-cut LN, 125±10° Y-cut LN, or 125±5° Y-cut LN. A thickness of the piezoelectric layer 12 can be selected based on a wavelength λ or L of a surface acoustic wave generated by the SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 12 can be sufficiently thick to avoid significant frequency variation. For example, the thickness of the piezoelectric layer 12 can be in a range of 0.1 L to 0.5, 0.1 L to 0.3 L, or 0.1 L to 0.2 L. Selecting the thickness of the piezoelectric layer 12 from these ranges can be critical in avoiding significant frequency variation and providing sufficient temperature coefficient of frequency for the SAW device 1. In some embodiments, the piezoelectric layer 12 can include lithium tantalate (LT) and lithium niobate (LN).

In some embodiments, the intermediate layer 13 can act as an adhesive layer. The intermediate layer 13 can include any suitable material. The intermediate layer 13 can be, for example, an oxide layer (e.g., a silicon dioxide (SiO₂) layer). One or more additional layers can be inserted between the intermediate layer 13 and the support substrate 10 to prevent or mitigate the unwanted electrical leakage on the surface of the support substrate 10. In some embodiments, one or more layers that include Poly-Si, amorphas Si, Porous Si, SiN, and/or AlN can be disposed between the intermediate layer 13 and the support substrate 10.

The IDT electrode 14 includes a first bus bar 20, a second bus bar 22, a first set of fingers 24 that extends from the first bus bar 20, and a second set of fingers 26 that extends from the second bus bar 22. The first bus bar 20 and the first set of fingers 24 can collectively referred to as a first electrode structure and the second bus bar 22 and the second set of fingers 26 can collectively referred to as a second electrode structure. The first set of fingers 24 includes a first finger 24a and the second set of fingers 26 includes a second finger 26a.

In the SAW device 1, the IDT electrode 14 has a single layer structure. However, in some other embodiments, the IDT electrode can have a multi-layer structure that includes separate IDT layers (e.g., the first layer and the second layer) that impact acoustic properties and electrical properties. In some embodiments, electrical properties, such as insertion loss, can be improved by adjusting one of the IDT layers without significantly impacting acoustic properties.

The IDT electrode 14 can include any suitable material. The IDT electrode 14 may include one or more other metals, such as aluminum (Al), copper (Cu), magnesium (Mg), titanium (Ti), tungsten (W), molybdenum (Mo), etc. The IDT electrode 14 may include alloys, such as AlMgCu, AlCu, etc. The IDT electrode 14 can be formed with (e.g., formed on or at least partially in) the piezoelectric layer 12. The piezoelectric layer 12 and the IDT electrode 14 can be provided in any suitable manner. For example, the piezoelectric layer 12 and the IDT electrode 14 can be provided in sequence. When the IDT electrode 14 is provided at least partially in the piezoelectric layer 12, the piezoelectric layer 12 can be partially etched and/or provided in a plurality of steps.

The SAW device 1 can include a first gap region GR1 between the first set of fingers 24 and the second bus bar 22, a second gap region GR2 between the second set of fingers 26 and the first bus bar 20, and an active region AR between the first and second gap regions GR1, GR2. The active region AR can be a region where the first and second sets of fingers 24, 26 interdigitate. The first bus bar 20 is positioned in a first bus bar region BBR1 and the second bus bar 22 is positioned in a second bus bar region BBR2.

The IDT electrode 14 has a first side S1 and a second side S2 separated by a centerline CL between the first and second bus bars 20, 22. A distance d1 from the first bus bar 20 to the centerline CL is the same as a distance d2 from the second bus bar 22 to the centerline CL. The SAW device 1 is asymmetric about the centerline CL between the first and second bus bars 20, 22. In some embodiments, the IDT electrode 14 is asymmetric (e.g., mass-asymmetric or structural-asymmetric) about the centerline CL. In the SAW device 1, the IDT electrode 14 in the first side S1 has a greater mass than the IDT electrode 14 in the second side S2. Also, in the SAW device 1, a width Wb1 of the first bus bar 20 can be greater than a width Wb2 of the second bus bar 22 making a size of the first bus bar 20 greater than a size of the second bus bar 22; a length l1 from an end of the second fingers 26 to the centerline CL can be greater than a length l2 from an end of the first fingers 24 to the centerline CL; and/or a gap g1 of the first gap region GR1 can be greater than a gap g2 of the second gap region GR2. The first and second fingers 24, 26 can be asymmetric about the centerline CL in the active region AR of the SAW device 1. Further, a profile of the first electrode structure including the first bus bar 20 and the first fingers 24 can be different from a profile of the second electrode structure that includes the second bus bar 22 and the second fingers 26. In other words, the shape of the first electrode structure would not be the same as the shape of the second electrode structure in any orientations.

In some embodiments, a difference between the mass of the IDT electrode 14 in the first side S1 and the mass of the IDT electrode 14 in the second side S2 can be in a range between 0.5% and 7%, 0.5% and 4%, 0.5% and 2.5%, 1% and 7%, 1% and 5%, or 1% and 4% of the mass of the IDT electrode 14 in the first side S1. In some embodiments, a difference between the width Wb1 of the first bus bar 20 and the width Wb2 of the second bus bar 22 can be in a range between 0.5% and 7%, 0.5% and 4%, 0.5% and 2.5%, 1% and 7%, 1% and 5%, or 1% and 4% of the width Wb1. In some embodiments, a difference between the length l1 from an end of the second fingers 26 to the centerline CL and the length l2 from an end of the first fingers 24 to the centerline CL can be in a range between 0.5% and 7%, 0.5% and 4%, 0.5% and 2.5%, 1% and 7%, 1% and 5%, or 1% and 4% of the length l1. In some embodiments, a difference between the gap g1 of the first gap region GR1 can be greater than a gap g2 of the second gap region GR2.

As noted above, the illustrated SAW device 1 is an example of an MPS-SAW device. The difference between the mass of the IDT electrode 14 in the first side S1 and the mass of the IDT electrode 14 in the second side S2 in different types of SAW devices can be different. For example, a difference between the mass of the IDT electrode 14 in the first side S1 and the mass of the IDT electrode 14 in the second side S2 in a TC-SAW device can be in a range between 15% and 25%, 18% and 22%, 18% and 20%, 15% and 22%, or 15% and 20% of the mass of the IDT electrode 14 in the first side S1.

The difference(s) between the first side S1 and the second side S2 can be greater when the cut angle of the piezoelectric layer (Y-cut X-propagation piezoelectric layer) deviates more from 0 or 90 degrees. The asymmetry of the SAW device 1 about the centerline CL can contribute to generating a substantially or effectively symmetric wave displacement.

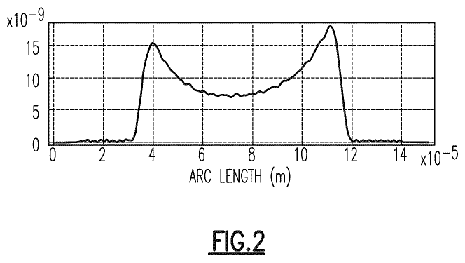

FIG. 2 is a graph showing a simulated wave displacement of the SAW device 1 shown in FIGS. 1A and 1B. FIG. 2 shows a substantially or effectively symmetric wave displacement. FIG. 2 indicates that the difference(s) between the first side S1 and the second side S2 in the SAW device 1 can provide a substantially symmetric wave displacement.

Any suitable features can be implemented in a SAW device to form an asymmetric SAW device. For example, a SAW device according to some embodiments can be mass-asymmetric while being symmetric in dimensions by implementing, for example, different materials with different mass densities. In some embodiments, an asymmetric or imbalanced piston mode or mass loading structure may be implemented in a SAW device. A piston mode or mass loading structure can contribute to transverse mode suppression enabling further performance improvement of a SAW device. For example, the piston mode structure may be formed only on one side of a SAW device to increase mass of the side of the SAW device. A mini-bus bar, a hammer head structure, a metal strip, a dummy finger, a multi-thickness IDT finger structure, or a piezoelectric layer trench are example structures that may be implemented as a piston mode structure.

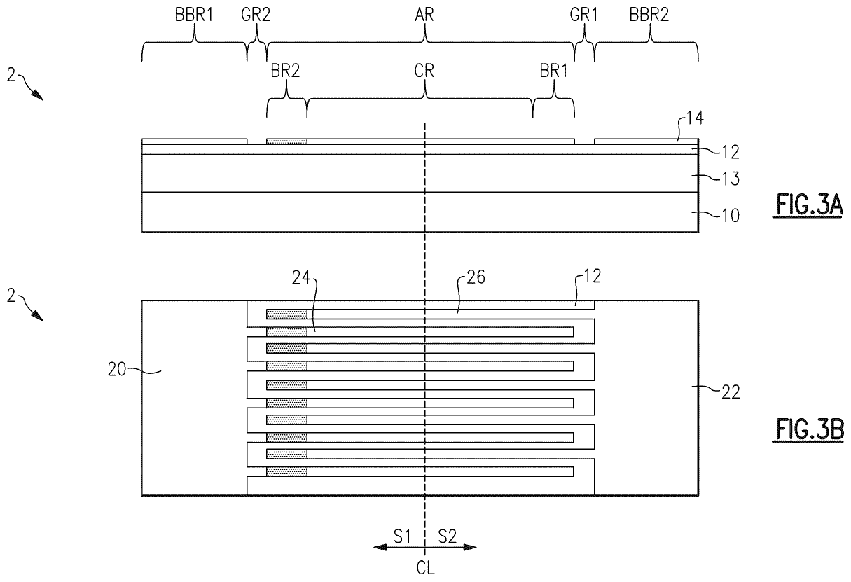

FIG. 3A is a schematic cross-sectional side view of a surface acoustic wave (SAW) device 2 according to an embodiment. FIG. 3B is a schematic top plan view of the SAW device 2. Unless otherwise noted, the components of the SAW device 2 shown in FIGS. 3A and 3B may be structurally and/or functionally the same as or generally similar to like components of other SAW devices disclosed herein.

The SAW device 2 is an example of an asymmetric SAW device. The SAW device 2 can include a support substrate 10, a piezoelectric layer 12, an intermediate layer 13 between the support substrate 10 and the piezoelectric layer 12, and an interdigital transducer (IDT) electrode 14 in electrical communication with the piezoelectric layer 12.

The SAW device 2 can include a first gap region GR1 between the first set of fingers 24 and the second bus bar 22, a second gap region GR2 between the second set of fingers 26 and the first bus bar 20, and an active region AR between the first and second gap regions GR1, GR2. The active region AR includes a center region CR, a first border region BR1 between the center region CR and the first gap region GR1, and a second border region BR2 between the center region CR and the second gap region GR2. The first bus bar 20 is positioned in a first bus bar region BBR1 and the second bus bar 22 is positioned in a second bus bar region BBR2. The first and second border regions BR1, BR2 can be regions within 0.5 L, 1 L, or 1.5 L of the first and second sets of fingers 24, 26 from respective edges of the first and second sets of fingers 24, 26 or from the respective first or second gap regions GR1, GR2.

The SAW device 2 is asymmetric about the centerline CL between the first and second bus bars 20, 22. The IDT electrode 14 of the SAW device 2 is mass-asymmetric about the centerline CL. In the SAW device 2, the IDT electrode 14 in the first side S1 has a greater mass than the IDT electrode 14 in the second side S2. In the SAW device 2, the IDT electrode 14 can include two or more materials. For example, the IDT electrode 14 can include a first material in the bus bar regions BBR1, BBR2, the gap regions GR1, GR2, the center region CR, and the first border region BR1, and a second material in the second border region BR2. In some embodiments, the second material can have a mass density that is greater than a mass density of the first material. For example, the second material can have a mass density that is in a range between 0.5% and 7%, 0.5% and 4%, 0.5% and 2.5%, 1% and 7%, 1% and 5%, or 1% and 4% greater than a mass density of the first material. In some other embodiments, the difference in mass between the IDT electrode 14 in the first side S1 and the IDT electrode 14 in the second side S2 can be achieved by having different thicknesses for the fingers 24, 26 in the border regions BR1, BR2.

In some embodiments, the IDT electrode 14 in the first border region BR1 and the second border region BR2 can have the second material. In such embodiments, changing the lengths of the border regions BR1, BR2 can make the asymmetric structure. For example, the length of the first border region BR1 can be in a range between 0.5% and 7%, 0.5% and 4%, 0.5% and 2.5%, 1% and 7%, 1% and 5%, or 1% and 4% greater than the length of the second border region BR2.

In the illustrated embodiment, a profile of the first electrode structure including the first bus bar 20 and the first fingers 24 can be the same as a profile of the second electrode structure that includes the second bus bar 22 and the second fingers 26. In other words, the shape of the first electrode structure can be the same as the shape of the second electrode structure in at least one orientation. However, in some other embodiments, the profile of the first electrode structure and the second electrode structure may be different while including two or more materials. As with the SAW device 1, the SAW device 2 can generate a substantially or effectively symmetric wave displacement.

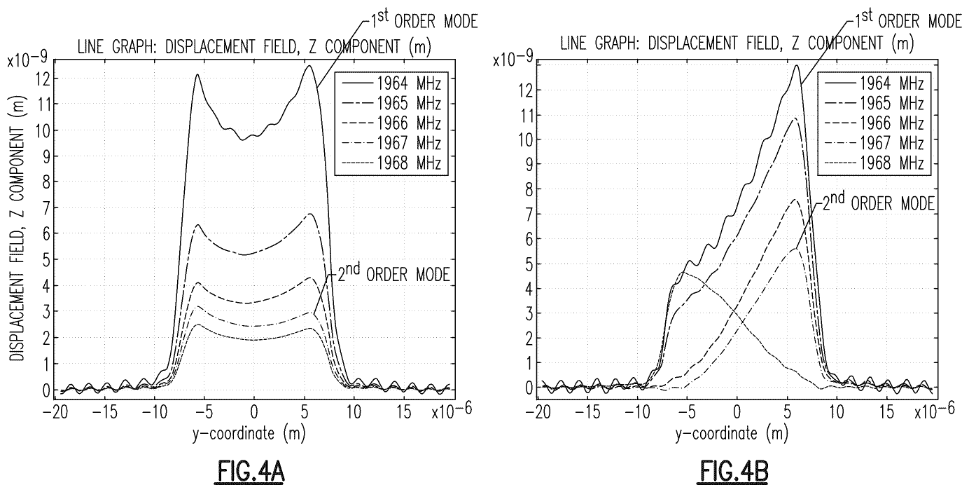

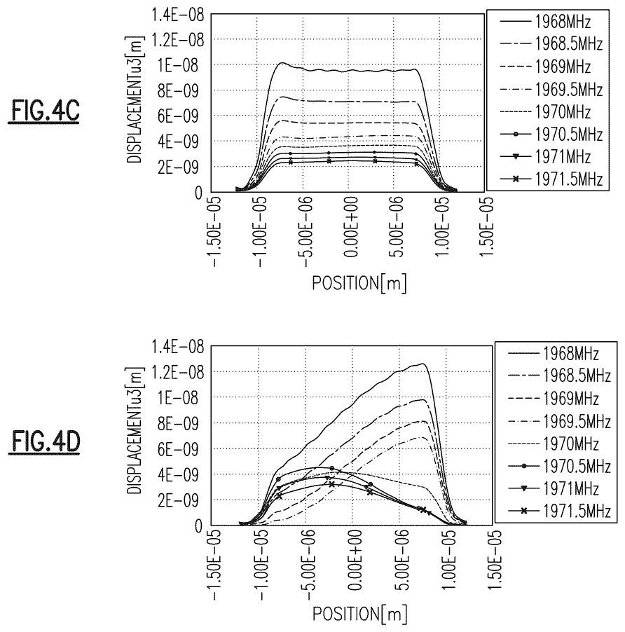

FIGS. 4A and 4C are graphs showing simulated wave displacements of the SAW device 2 shown in FIGS. 3A and 3B with different border region configurations. FIGS. 4B and 4D are graphs showing simulated wave displacements of symmetric SAW devices. The SAW device 2 and the symmetric SAW devices used in the simulations of FIGS. 4A to 4D have identical shapes. However, the IDT electrode fingers of the symmetric SAW device includes a first material in the center region and a second material in the first and second border regions but the first and second fingers 24, 26 of the SAW device 2 includes the first material in the center region and the first border region BR1 and the second material in the second border region BR2. The difference between the devices used in FIGS. 4A and 4B and FIGS. 4C and 4D are the size of the border regions BR1, BR2. The mass density of the second material of the IDT electrode in the second border region BR2 used in the simulation of FIG. 4A is 1.025 times the mass density of the first material of the IDT electrode.

FIGS. 4A and 4C show substantially or effectively symmetric wave displacements, and FIGS. 4B and 4D show asymmetric wave displacements. FIGS. 4A to 4D indicate that the difference in mass between the first side S1 and the second side S2 in the SAW device 2 can make the asymmetric wave displacement of a symmetric SAW device to a more symmetric wave displacement.

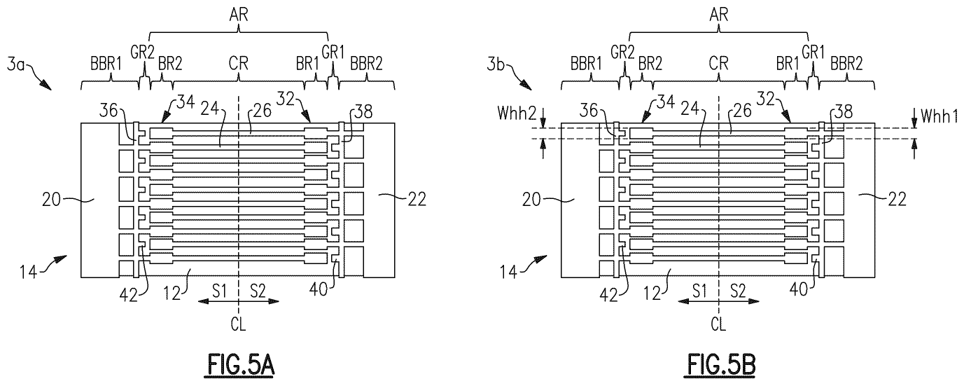

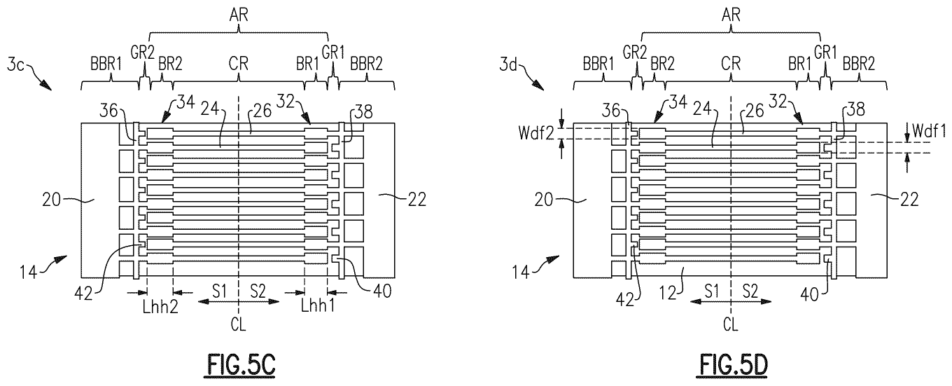

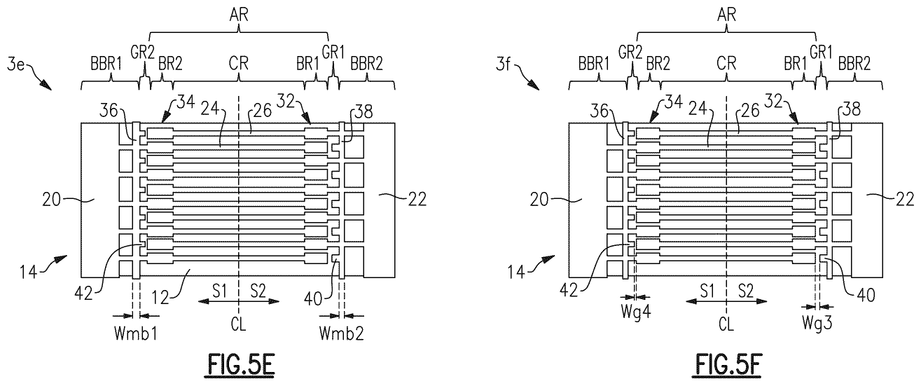

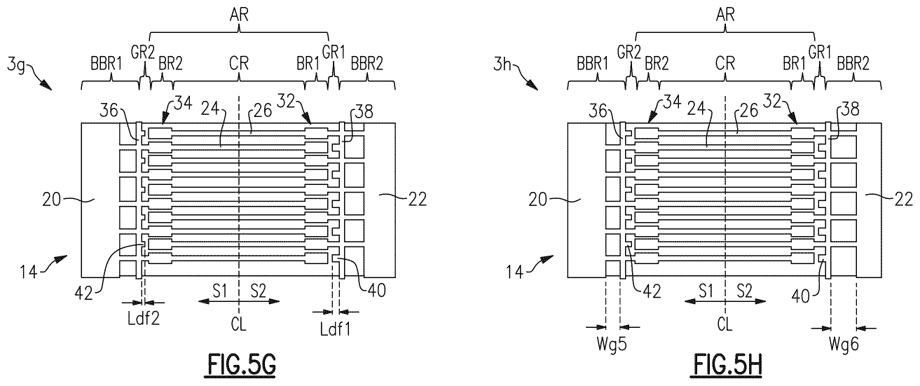

FIGS. 5A to 5H show SAW devices that include piston mode structures. The piston mode structures can include, for example, a hammer head structure, a mini-bus bar, or a dummy finger. Sizes of the hammer head structures, the mini-bus bars, and/or the dummy fingers included in a SAW device can be different to make the SAW device an asymmetric SAW device.

FIG. 5A is a schematic top plan view of a symmetric SAW device 3a. FIGS. 5B to 5H are schematic top plan views of SAW devices 3b, 3c, 3d, 3e, 3f, 3g, 3h according to various embodiments. The SAW devices 3b, 3c, 3d, 3e, 3f, 3g, 3h of FIGS. 5B to 5H are examples of asymmetric SAW devices. Unless otherwise noted, the components of the SAW devices 3b, 3c, 3d, 3e, 3f, 3g, 3h of FIGS. 5B to 5H may be structurally and/or functionally the same as or generally similar to like components of other SAW devices disclosed herein.

The SAW devices 3a, 3b, 3c, 3d, 3e, 3f, 3g, 3h of FIGS. 5A to 5H can include a first set of hammer head structures 32 in the first border region BR1, a second set of hammer head structures 34 in the second border region BR2, a first mini-bus bar 36 in the first bus bar region BBR1, a second mini-bus bar 38 in the second bus bar region BBR2, a first set of dummy fingers 40 in the first gap region GR1, and a second set of dummy fingers 42 in the second gap region GR2.

A width Whh2 of the second hammer head structures 34 can be different from a width Whh1 of the first hammer head structure 32. For example, as illustrated in FIG. 5B, the width Whh2 of the second hammer head structures 34 can be greater than the width Whh1 of the first hammer head structures 32. In the SAW device 3b, the first side S1 of the IDT electrode 14 can have a greater mass than a mass of the second side S2 of the IDT electrode 14.

A length Lhh2 of the second hammer head structures 34 can be different from a length Lhh1 of the first hammer head structure 32. For example, as illustrated in FIG. 5C, the length Lhh2 of the second hammer head structures 34 can be greater than the length Lhh1 of the first hammer head structures 32. In the SAW device 3c, the first side S1 of the IDT electrode 14 can have a greater mass than a mass of the second side S2 of the IDT electrode 14.

A width Wdf2 of the second dummy fingers 42 can be different from a width Wdf1 of the first dummy fingers 40. For example, as illustrated in FIG. 5D, the width Wdf2 of the second dummy fingers 42 can be greater than the width Wdf1 of the first dummy fingers 40. In the SAW device 3d, the first side S1 of the IDT electrode 14 can have a greater mass than a mass of the second side S2 of the IDT electrode 14.

A width Wmb1 of the first mini-bus bar 36 can be different from a width Wmb2 of the second mini-bus bar 38. For example, as illustrated in FIG. 5E, the width Wmb1 of the first mini-bus bar 36 can be greater than the width Wmb2 of the second mini-bus bar 38. In the SAW device 3e, the first side S1 of the IDT electrode 14 can have a greater mass than a mass of the second side S2 of the IDT electrode 14.

A width Wg4 of the gap between the second dummy fingers 42 and the second fingers 26 can be different from a width Wg3 of the gap between the first dummy fingers 40 and the first fingers 24. For example, as illustrated in FIG. 5F, the width Wg4 can be smaller than the width Wg3. In the SAW device 3f, the first side S1 of the IDT electrode 14 can have a greater mass than a mass of the second side S2 of the IDT electrode 14.

A length Ldf2 of the second dummy fingers 42 can be different from a length Ldf1 of the first dummy fingers 40. For example, as illustrated in FIG. 5G, the length Ldf2 of the second dummy fingers 42 can be smaller than the length Ldf1 of the first dummy fingers 40. In the SAW device 3g, the second side S2 of the IDT electrode 14 can have a greater mass than a mass of the first side S1 of the IDT electrode 14.

A width Wg5 of the gap between the first bus bar 20 and the first mini-bus bar 36 can be different from a width Wg6 of the gap between the second bus bar 22 and the second mini-bus bar 38. For example, as illustrated in FIG. 5H, the width Wg5 can be smaller than the width Wg6 by making the width Wb2 of the second bus bar 22. In the SAW device 3h, the first side S1 of the IDT electrode 14 can have a greater mass than a mass of the second side S2 of the IDT electrode 14.

A piezoelectric layer trench is another example structure that may be implemented as a piston mode structure in a SAW device. The piezoelectric layer trench can be formed at a surface of a piezoelectric layer. The piezoelectric layer trench can be located, for example, between a bus bar and a center region.

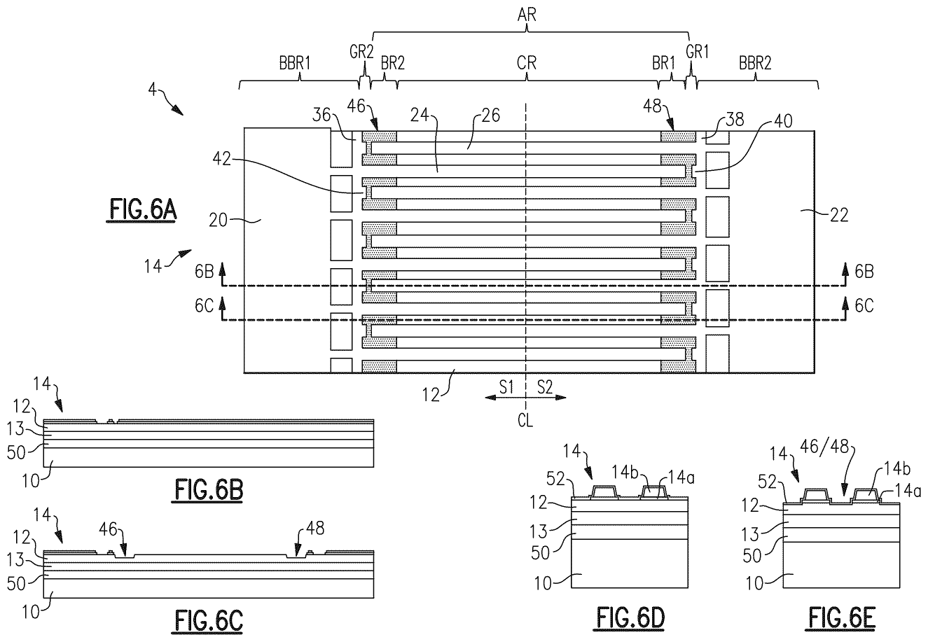

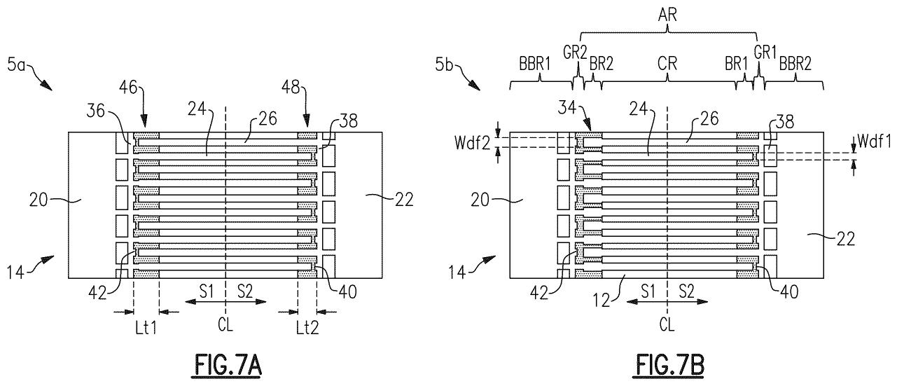

FIG. 6A is a schematic top plan view of a symmetric SAW device 4 that includes piezoelectric layer trenches 46, 48. FIGS. 6B to 6E are schematic cross-sectional side views of the symmetric SAW device 4. The cross-section of FIG. 6D is in the center region CR, and the cross-section of FIG. 6E is in the border region BR1/BR2.

The symmetric SAW device 4 can include a support substrate 10, a piezoelectric layer 12, an intermediate layer 13 between the support substrate 10 and the piezoelectric layer 12, a trap-rich layer 50 between the support substrate and the intermediate layer 13, an IDT electrode 14 in electrical communication with the piezoelectric layer 12, and a passivation layer 52 over the IDT electrode 14 (only shown in FIGS. 6D and 6E). The IDT electrode 14 can include a first mini-bus bar 36 in the first bus bar region BBR1, a second mini-bus bar 38 in the second bus bar region BBR2, a first set of dummy fingers 40 in the first gap region GR1, and a second set of dummy fingers 42 in the second gap region GR2. The piezoelectric layer trench 46 can be located between the first bus bar region BBR1 and the center region CR, and the piezoelectric layer trench 48 can be located between the second bus bar region BBR2 and the center region CR.

The first fingers 24 between the first bus bar 20 and the first mini-bus bar 36 can be narrower than the first fingers 24 in the active region AR. Similarly, the second fingers 26 between the second bus bar 22 and the second mini-bus bar 38 can be narrower than the second fingers 26 in the active region AR.

The IDT electrode 14 can include a first layer 14a and a second layer 14b. The first layer 14a of the IDT electrode 14 can be referred to as a lower electrode layer. The first layer 14a of the IDT electrode 14 is disposed between the second layer 14b of the IDT electrode 14 and the piezoelectric layer 12. As illustrated, the first layer 14a of the IDT electrode 14 can have a first side in physical contact with the piezoelectric layer 12 and a second side in physical contact with the second layer 14b of the IDT electrode 14. The second layer 14b of the IDT electrode 14 can be referred to as an upper electrode layer. The second layer 14b of the IDT electrode 14 can be disposed over the first layer 14a of the IDT electrode 14. As illustrated, the second layer 14b of the IDT electrode 14 can have a first side in physical contact with the first layer 14a of the IDT electrode 14.

The trap rich layer 50 can be formed at, near, on, or with the support substrate 10. In some embodiments, the trap rich layer 50 can mitigate the parasitic surface conductivity of the support substrate 10. The trap rich layer 50 can be formed in a number of ways, for example, by forming the surface of the support substrate 10 with amorphous or polycrystalline silicon, by forming the surface of the support substrate 10 with porous silicon, or by introducing defects into the surface of the support substrate 10 via ion implantation, ion milling, or other methods. In some embodiments, the trap rich layer 50 can improve the electrical characteristics of a SAW device by increasing the depth and sharpness on the anti-resonance peak.

FIGS. 7A and 7B are schematic top plan views of SAW devices 5a, 5b according to various embodiments. Unless otherwise noted, the components of the SAW devices 5a, 5b shown in FIGS. 7A and 7B may be structurally and/or functionally the same as or generally similar to like components of other SAW devices disclosed herein. The SAW devices 5a, 5b can be generally similar to the symmetric SAW device 4. However, unlike the symmetric SAW device 4, the SAW devices 5a, 5b include various features that make the SAW devices 5a, 5b asymmetric SAW devices.

A length Lt1 of the piezoelectric trench 46 in the first side S1 can be different from a length Lt2 of the piezoelectric trench 48 in the second side S2. For example, in the SAW device 5a shown in FIG. 7A, the length Lt1 of the piezoelectric trench 46 in the first side S1 can be smaller than the length Lt2 of the piezoelectric trench 48 in the second side S2. The difference in the lengths Lt1 and Lt2 can make the SAW device 5a an asymmetric SAW device.

A width Wfb1 of the fingers 24, 26 in the first border region BR1 can be different from a width Wfb2 of the fingers 24, 26 in the second border region BR2. For example, in the SAW device 5b shown in FIG. 7B, the width Wfb2 can be smaller than the width Wfb1. The difference in the width Wfb1 and Wfb2 can make the SAW device 5b an asymmetric SAW device.

Any suitable principles and advantages disclosed herein can be combined in a single SAW device. Symmetric SAW devices used herein include substantially symmetric SAW devices that are not perfectly symmetric about their centerline. Asymmetric SAW devices disclosed herein do not encompass such substantially symmetric SAW devices that are intended to be symmetric but are not perfectly symmetric due to manufacturing tolerances. Various embodiments disclosed herein are described using MPS-SAW devices. However, any suitable principles and advantages disclosed herein can also be beneficial when implemented in other types of SAW devices, such as a TC-SAW device.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more conductive structures disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

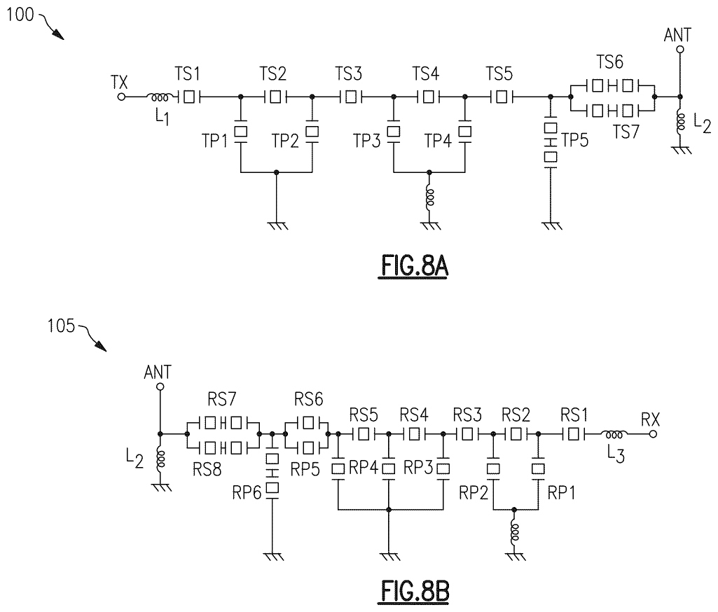

FIG. 8A is a schematic diagram of an example transmit filter 100 that includes surface acoustic wave devices according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 8B is a schematic diagram of a receive filter 105 that includes surface acoustic wave devices according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 8A and 8B illustrate example ladder filter topologies, any suitable filter topology can include a conductive structure in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

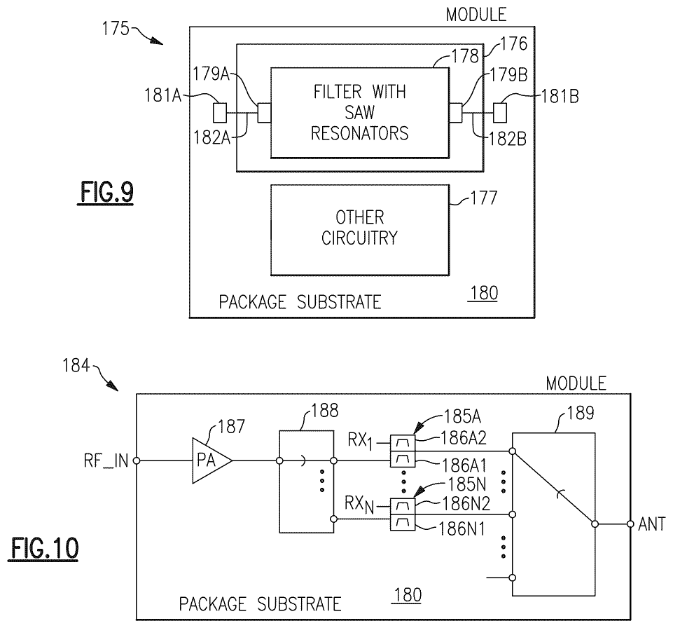

FIG. 9 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 9 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 9. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

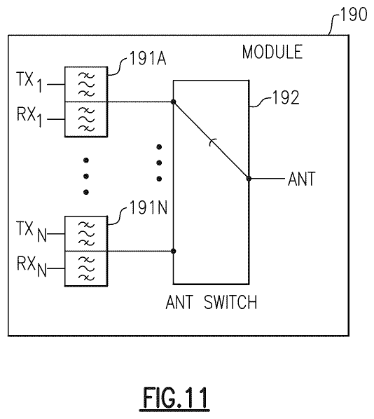

FIG. 10 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 11 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

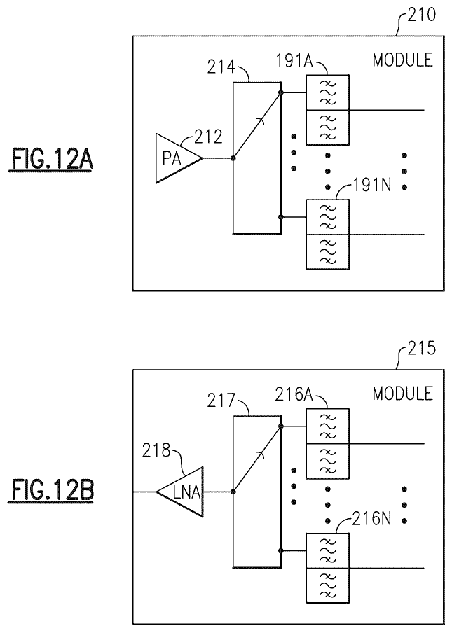

FIG. 12A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 12B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

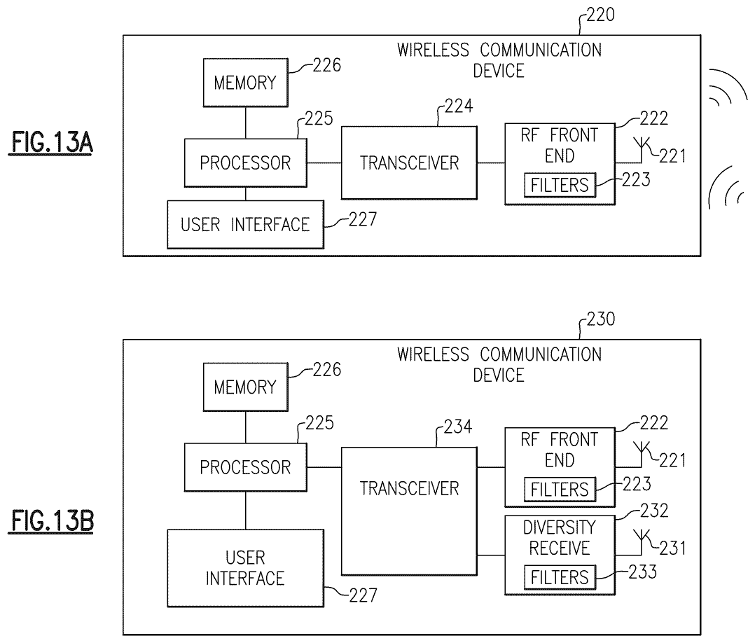

FIG. 13A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 13B is a schematic diagram of a wireless communication device 230 that includes filters 223 in a radio frequency front end 222 and a second filter 233 in a diversity receive module 232. The wireless communication device 230 is like the wireless communication device 220 of FIG. 13A, except that the wireless communication device 230 also includes diversity receive features. As illustrated in FIG. 13B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a piezoelectric layer; and
an interdigital transducer electrode in electrical communication with the piezoelectric layer, the interdigital transducer electrode including a first bus bar, first fingers extending from the first bus bar, a second bus bar, and second fingers extending from the second bus bar, the interdigital transducer electrode having a first side and a second side separated by a centerline between the first bus bar and the second bus bar, a first mass of the first side of the interdigital transducer electrode being different from a second mass of the second side of the interdigital transducer electrode.

2. The surface acoustic wave device of claim 1 wherein a difference between the first mass and the second mass is in a range between 0.5% and 4% of the first mass.

3. The surface acoustic wave device of claim 1 wherein a difference between the first mass and the second mass is in a range between 18% and 22% of the first mass.

4. The surface acoustic wave device of claim 1 wherein a size of the first bus bar and a size of the second bus bar are different.

5. The surface acoustic wave device of claim 1 wherein a length of the first fingers and a length of the second fingers are different.

6. The surface acoustic wave device of claim 1 wherein a gap between the first fingers and the second bus bar and a gap between the second fingers and the first bus bar are different.

7. The surface acoustic wave device of claim 1 having an active region including a first border region, a second border region, and a center region between the first and second border regions, wherein the first fingers have a greater mass in the second border region than in the first border region.

8. The surface acoustic wave device of claim 7 wherein the first fingers in the first border region are made with a first material and the second fingers in the second border region are made with a second material different from the first material.

9. The surface acoustic wave device of claim 7 wherein the first fingers in the first border region have a first width and the second fingers in the second border region have a second width different from the first width.

10. The surface acoustic wave device of claim 7 wherein the first fingers in the first border region have a first thickness and the second fingers in the second border region have a second thickness different from the first thickness.

11. The surface acoustic wave device of claim 1 wherein the interdigital transducer electrode further includes a first mini-bus bar between the first bus bar and the second fingers.

12. The surface acoustic wave device of claim 11 wherein the interdigital transducer electrode further includes a second mini-bus bar between the second bus bar and the first fingers, and the first mini-bus bar has a greater width than the second mini-bus bar.

13. The surface acoustic wave device of claim 1 wherein the interdigital transducer electrode further includes first dummy fingers between the first bus bar and the second fingers.

14. The surface acoustic wave device of claim 13 wherein the interdigital transducer electrode further includes second dummy fingers between the second bus bar and the first fingers.

15. The surface acoustic wave device of claim 14 wherein the first dummy fingers have a length that is greater than a length of the second dummy fingers, and the piezoelectric layer has a trench.

16. The surface acoustic wave device of claim 1 further comprising a support substrate and an intermediate layer between the support substrate and the piezoelectric layer.

17. A surface acoustic wave device comprising:
a piezoelectric layer; and
an interdigital transducer electrode in electrical communication with the piezoelectric layer, the interdigital transducer electrode including a first bus bar, first fingers extending from the first bus bar, a second bus bar, and second fingers extending from the second bus bar, the interdigital transducer electrode being mass-asymmetric about a centerline between the first bus bar and the second bus bar.

18. The surface acoustic wave device of claim 17 wherein the interdigital transducer electrode has a first side and a second side separated by the centerline between the first bus bar and the second bus bar, a first mass of the first side of the interdigital transducer electrode is greater than a second mass of the second side of the interdigital transducer electrode.

19. The surface acoustic wave device of claim 18 having an active region including a first border region, a second border region, and a center region between the first and second border regions, wherein the center region being symmetric about the centerline.

20. An acoustic wave filter comprising:
a surface acoustic wave device including a piezoelectric layer and an interdigital transducer electrode in electrical communication with the piezoelectric layer, the interdigital transducer electrode including a first bus bar, first fingers extending from the first bus bar, a second bus bar, and second fingers extending from the second bus bar, the interdigital transducer electrode having a first side and a second side separated by a centerline between the first bus bar and the second bus bar, a first mass of the first side of the interdigital transducer electrode being different from a second mass of the second side of the interdigital transducer electrode; and
one or more other acoustic wave devices coupled to the surface acoustic wave device.
